(19) United States
(12) Patent Application Publication
(10) Pub. No.: US 2013/0181301 A1
(43) Pub. Date: Jul. 18, 2013

(54) METHOD FOR MANUFACTURING A FIELD-EFFECT SEMICONDUCTOR DEVICE FOLLOWING A REPLACEMENT GATE PROCESS

(71) Applicants: IMEC, Leuven (BE); Katholieke Universiteit Leuven, Leuven (BE)

(72) Inventors: Liesbeth Witters, Everberg (BE); Jerome Mitard, Tourinnes-La-Grosse (BE); Geert Hellings, Heverlee (BE)

(73) Assignees: Katholieke Universiteit Leuven, Leuven (BE); IMEC, Leuven (BE)

(21) Appl. No.: 13/725,587

(22) Filed: Dec. 21, 2012

(30) Foreign Application Priority Data
Dec. 23, 2011 (EP) 11195617.3

(51) Int. Cl. H01L 29/66; H01L 29/78

(52) U.S. Cl. CPC H01L 29/66477; H01L 29/78
USPC 257/408; 438/306

(57) ABSTRACT

A method of manufacturing a semiconductor device is disclosed. In one aspect, the method includes: forming a dummy gate over a substrate layer; forming first gate insulating spacers adjacent to sidewalls of the dummy gate and over the substrate layer, the first spacers having two sidewalls and two surface profiles where the sidewalls meet the substrate layer; forming a source and drain region using the surface profiles; forming second gate insulating spacers adjacent to the sidewalls of the first spacers and over the source and drain regions; removing the dummy gate and the first spacers, thereby forming a first recess; depositing a dielectric layer in the first recess along the side walls of the second spacers and over the substrate layer, thereby forming a second recess; and depositing a gate electrode in the second recess.

### BACKGROUND OF THE INVENTION

1. Field of the Invention

The disclosed technology relates generally to field-effect semiconductor devices, such as field-effect transistors (FETs), and more specifically to a method for manufacturing a field effect semiconductor device following a replacement gate process.

2. Description of the Related Technology

Several challenges still remain for large scale integration of field-effect semiconductor devices. As FET transistor gate lengths continue to scale down, the offset spacer design becomes critical for transistor performance. The required dimensions of such dielectric offset spacers, also referred to as sidewall spacers, are increasingly smaller and the processes to define the offset spacer profile are increasingly difficult to control in order to achieve the desired critical dimensions.

Therefore there is a need to address the heightened sensitivity to gate spacer dimensioning using process techniques for gate sidewall spacer formation, particularly in manufacturing processes following a gate-last approach, also called replacement gate or damascene gate processes.

US patent application, for example, 2007/0287259 A1 discloses the use of gate isolation spacers in a method of forming a semiconductor structure according to a replacement gate process.

Also, in US patent application 2006/0148182 A1, a self-aligned source drain quantum well transistor or high electron mobility transistor is formed using a replacement metal gate process, in which sidewall spacers temporarily bracket a dummy gate electrode.

A problem with the current techniques for manufacturing FET devices is that they lack a precise control of the distance from the source/drain extensions to the gate edge.

### SUMMARY OF CERTAIN INVENTIVE ASPECTS

Certain inventive aspects relate to an improved FET device and method for manufacturing the same, using a replacement gate process, which overcomes current FET design source/drain extension underlap and overlap drawbacks.

According to one inventive aspect, a method for manufacturing a field-effect semiconductor device is provided, the method comprising: forming a temporary dummy gate over a substrate layer; forming temporary first gate insulating spacers adjacent to the sidewalls of the dummy gate and over the substrate layer, the temporary first gate insulating spacers comprising two lateral side walls and presenting two outer surface profiles where the lateral side walls meet the substrate layer; forming a source region and a drain region in and/or over the substrate layer using the temporary first gate insulating spacers lateral side walls surface profiles; forming second gate insulating spacers adjacent to the sidewalls of the temporary first gate insulating spacers and over the source and drain regions; removing the temporary dummy gate and the temporary first gate insulating spacers, thereby forming a first gate recess space; depositing a dielectric layer in the first gate recess space, directly along the side walls of the second gate sidewall insulating spacers and over the substrate layer, thereby forming a second gate recess space; and depositing a gate electrode in the second gate recess space.

Advantageously field-effect semiconductor devices manufactured according to one inventive aspect avoid sensitivity to offset spacer critical dimension and present reduced sensitivity towards S/D-gate overlap/underlap variations, which greatly impact the transistor performance.

Advantageously, the method for manufacturing a field-effect semiconductor device according to one aspect allows better control and design of the device performance characteristics (e.g., resistance, capacitance and gate-drain leakage) by providing a mechanism to increase precision control for defining the source and drain region distance to the gate electrode edges, e.g. for both overlap and underlap field-effect semiconductor device design. In that sense, the method according to one aspect advantageously allows better repeatability of the field-effect semiconductor device performance characteristics.

The method according to one aspect can be advantageously applied for manufacturing both planar devices, such as, for example, implant-free quantum well (IFQW) FET devices or silicon on oxide (SOT) pFET devices, and non-planar FET devices such as FinFET devices. Advantageously, in case of non-planar devices, the S/D-gate overlap/underlap distance along the FIN walls is more precisely controlled, and for example, a fixed external resistance (Rext) along the FIN walls is achieved.

According to another aspect the step of forming the source and drain region comprises using the surface profiles of the temporary first gate insulating spacers lateral side walls to align the source/drain regions, in or over the substrate layer, to those surface profiles.

According to still another aspect, the step of forming the source and drain region comprises using the surface profiles of the temporary first gate insulating spacers lateral side walls to define the source/drain region extension, in the substrate layer, under the dummy gate.

Advantageously, according to one aspect, the surface profile of the temporary first gate insulating spacers lateral side walls is set and used as a reference point to align the source/drain regions over the substrate layer, e.g. by epitaxial overgrowth of the source/drain regions, or as a mask to align the source/drain regions in the substrate layer, or to define the source/drain region extension in the substrate under the dummy gate by, for example, first etching the substrate layer starting from the surface profile of the temporary first gate insulating spacers lateral side walls and then filling the etched openings to form the source/drain regions.

According to still another aspect, the step of forming the source and drain region comprises using the surface profiles of the temporary first gate insulating spacers lateral side walls to align the source/drain regions, over the substrate layer, to the surface profiles and to define the source/drain region extension, in the substrate layer, under the dummy gate.

According to one aspect, the temporary first gate insulating spacers are removed after the temporary dummy gate removal, thereby forming a first gate recess space.

According to another aspect, the method comprises forming a temporary dummy dielectric between the dummy gate and the substrate layer, and the step of removing the temporary dummy gate and the temporary first gate insulating spacers comprises also removing the dummy dielectric, thereby forming the first gate recess space.

According to another aspect, the step of removing the temporary first gate insulating spacers comprises selectively removing the material of the temporary first gate insulating spacers without substantially removing the material of the second gate insulating spacers, for example by etching out the material of the temporary first gate insulating spacers without substantially removing the material of the second gate insulating spacers, e.g. with a selectivity ratio higher than about 2 to 1. In one example, the temporary first gate insulating spacers are made of an oxide material and the second gate insulating spacers are made of a dense nitride material. In another example, the temporary first gate insulating spacers are made of a nitride component deposited at temperatures lower than about 480 C and designed to etch faster in hydrofluoric acid than the material of the second gate insulating spacers.

According to another aspect, the substrate layer comprises at least one silicon wafer layer, at least a silicon wafer layer and a quantum well layer, or at least a silicon wafer layer, a buried oxide layer and a silicon layer.

One inventive aspect also relates to field-effect semiconductor devices and associated devices, e.g. integrated or electronic circuits comprising one or a plurality of the FET devices manufactured according to the method described herein.

Certain objects and advantages of various inventive aspects have been described above. It is to be understood that not necessarily all such objects or advantages may be achieved in accordance with any particular embodiment of the invention. Those skilled in the art will recognize that the invention may be embodied or carried out in a manner that achieves or optimizes one advantage or group of advantages without necessarily achieving other objects or advantages as may be taught or suggested herein.

### BRIEF DESCRIPTION OF THE DRAWINGS

The above and other aspects of the invention will be apparent from the following description and with reference to the non-restrictive example embodiment(s) described hereinafter.

FIG. 1A is a cross-sectional view of one embodiment of the invention at an early stage of manufacture.

FIG. 1B is a top view of the embodiment shown in FIG. 1A.

FIG. 2 is a cross-sectional view of the embodiment shown in FIG. 1A in a subsequent step of manufacture.

FIG. 3 is a cross-sectional view of the embodiment shown in FIG. 2 in a subsequent step of manufacture.

FIG. 4 is a cross-sectional view of one embodiment of a field-effect semiconductor device after completion of the gate stack stage of manufacture comprising the manufacturing steps shown in FIGS. 1 to 3.

FIG. 5 is a cross-sectional view of another embodiment of the invention at an early stage of manufacture.

FIG. 6 is a cross-sectional view of one embodiment of a field-effect semiconductor device after completion of the gate stack stage of manufacture comprising the manufacturing step of FIG. 5.

FIG. 7 is a cross-sectional view of still another embodiment of the invention at an early stage of manufacture.

FIG. 8 is a cross-sectional view of the embodiment shown in FIG. 7 in a subsequent step of manufacture.

FIG. 9 is a cross-sectional view of the embodiment shown in FIG. 8 in a subsequent step of manufacture.

FIG. 10 is a cross-sectional view of the embodiment shown in FIG. 9 in a subsequent step of manufacture.

FIG. 11 is a cross-sectional view of one embodiment of a field-effect semiconductor device after completion of the gate stack stage of manufacture comprising the manufacturing steps shown in FIGS. 7 to 10.

FIG. 12 is a cross-sectional view of one embodiment of a field-effect semiconductor device after completion of the gate stack stage of manufacture.

FIG. 13 is a schematic 3D view of a non-planar field-effect semiconductor device at an early stage of manufacture according to an exemplary embodiment.

### DETAILED DESCRIPTION OF CERTAIN ILLUSTRATIVE EMBODIMENTS

In the following, it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This is however not to be interpreted as the invention requiring more features than the ones expressly recited in each claim, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those skilled in the art.

In the description of the embodiments, numerous specific details are set forth.

However, it is understood that embodiments of the invention may be practiced without these non-essential specific details. In other instances, well-known methods, structures and techniques have not been shown in detail in order not to obscure an understanding of this description.

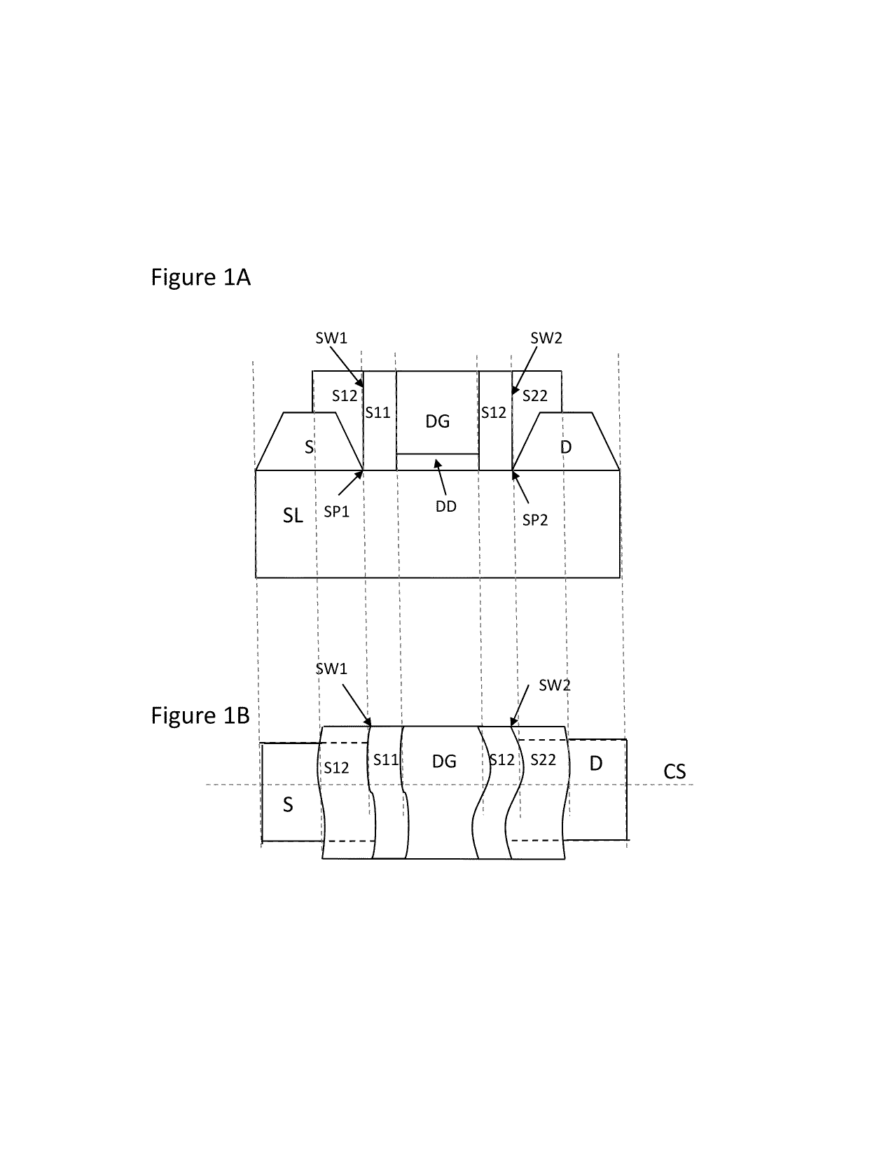

FIG. 1A is a cross-sectional view, across line CS of FIG. 1B, of one embodiment of the invention at an early stage of manufacture, comprising a substrate layer SL, a source region S and a drain region D, a dummy gate DG, a dummy dielectric DD, a first pair of gate insulating spacers S11 and S12 presenting two lateral side walls SW1 and SW2 in the length direction of the field-effect semiconductor device channel and two outer surface profiles SP1 and SP2 where the lateral side walls meet the substrate layer SL, and a pair of second gate insulating spacers S21 and S22.

The first gate insulating spacers can be also called first offset spacer or first sacrificial spacers, and are sacrificial spacers laid along the walls of the dummy gate. It shall also be understood that, in the following embodiments, the elements of the figures are shown schematically and for illustration purposes only and therefore the real geometry of those elements may vary when implemented.

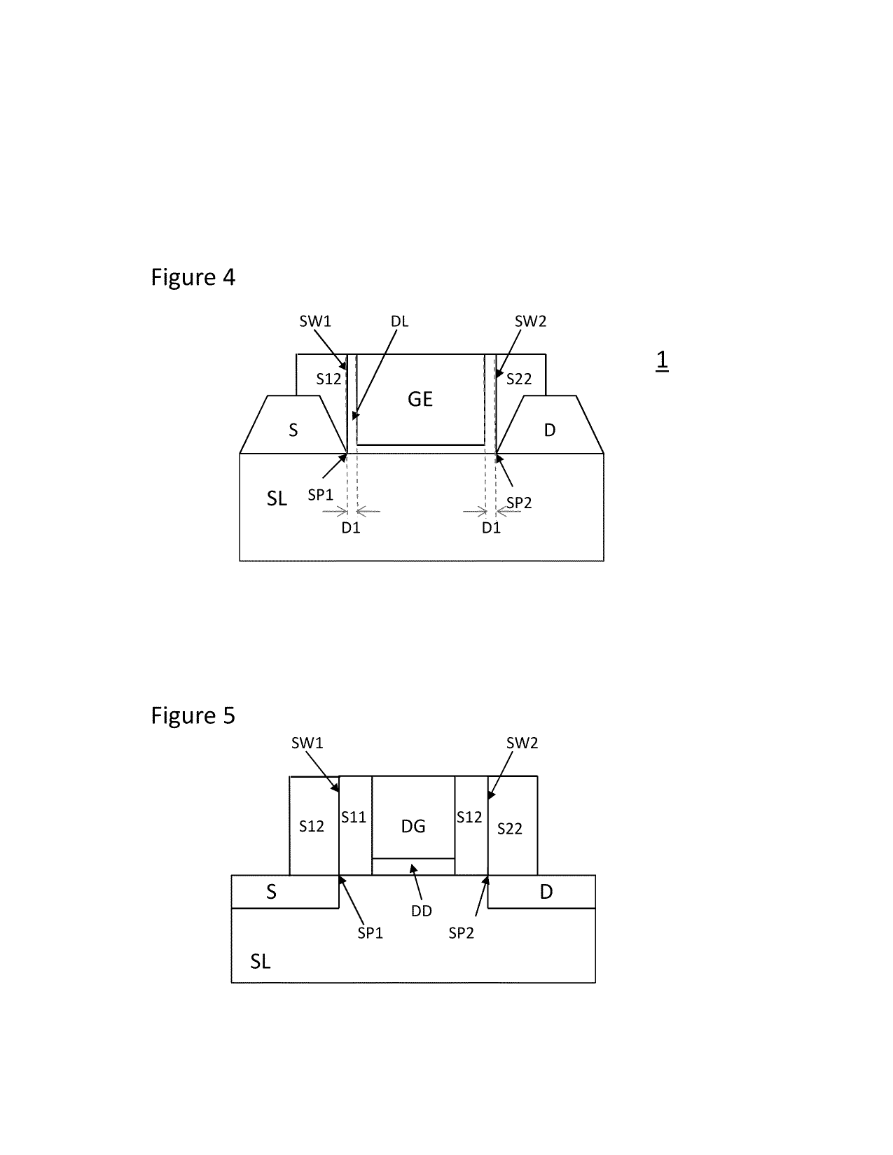

Manufacturing of the field-effect semiconductor device 1 of FIG. 4 may begin by forming the embodiment of FIGS. 1A and 1B according to the following: in a first step a temporary dummy dielectric DD and a temporary dummy gate DG are formed over a substrate layer SL; in a second step, a pair of temporary first gate insulating spacers S11 and S12 are formed adjacent to the sidewalls of the dummy gate DG and over the substrate layer SL so that the temporary first gate insulating spacers present two lateral side walls SW1 and SW2 and two outer surface profiles SP1 and SP2 where the lateral side walls meet the substrate layer SL; in a third step, a source region S and a drain region D are formed over the substrate layer SL using the surface profiles of the temporary gate insulating spacers lateral side walls; in a fourth step, a pair of second gate insulating spacers S21 and S22 are formed adjacent to the sidewalls of the temporary first gate insulating spacers S11 and S12 and over the source and drain regions.

According to one embodiment of the invention, as shown in FIGS. 1A and 1B, the source and drain regions are grown over the substrate layer SL and extend along the temporary first gate insulating spacers lateral side walls surface profiles SP1 and SP2, so that they are aligned to those surface profiles. According to the embodiment of the invention, the temporary first gate insulating spacers S11 and S12 limit the source/drain region extension in the direction of the gate.

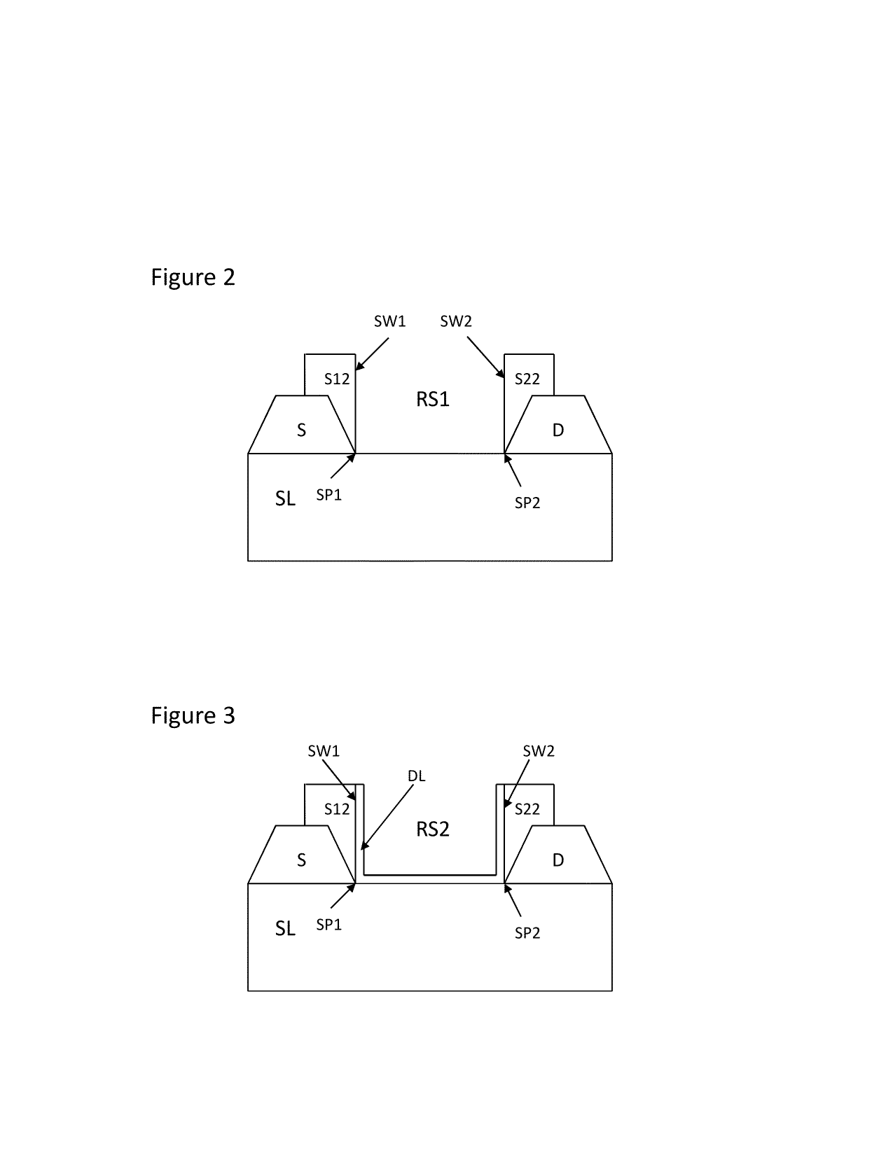

In subsequent steps of manufacture of the field-effect semiconductor device 1 of FIG. 4, the temporary dummy gate DG, the temporary dummy dielectric DD and the temporary first gate insulating spacers S11 and S12 are removed, so as to form a first gate recess space RS1, as shown in FIG. 2.

In one embodiment, the temporary first gate insulating spacers S11 and S12 are made of material different from the material of the temporary dummy gate, and the temporary first gate insulating spacers S11 and S12 are removed after having removed that dummy gate. In that case, more definition control over the first gate recess boundaries close to the second gate insulating spacers S21 and S22 is achieved. It shall be understood that the presence of the temporary dummy dielectric DD under the temporary dummy gate structure DG is optional, and that the dummy dielectric DD may be advantageous to achieve better control definition over the first gate recess boundaries close to the substrate layer. According to another embodiment, the temporary first gate insulating spacers S11 and S12 are made of a material which allows removing the first gate spacers without substantially removing the material of the second gate insulating spacers S21 and S22, for example, by etching out the material with a selectivity ratio higher than about 2 to 1. In one example, the temporary first gate insulating spacers are made of an oxide material and the second gate insulating spacers are made of a dense nitride material. In another example, the temporary first gate insulating spacers are made of a nitride component deposited at temperatures lower than about 480 C and designed to etch faster in hydrofluoric acid than the material of the second gate insulating spacers.

Now referring to the FIG. 3, which shows an embodiment in a subsequent step of manufacture of the field-effect semiconductor device 1 of FIG. 4, a dielectric layer DL is deposited in the first gate recess space RS1, along the side walls of the second gate sidewall insulating spacers S21 and S22 and over the substrate layer SL, so as to form a second gate recess space RS2.

According to one embodiment, the dielectric layer DL is made of a material with high dielectric constant value. Advantageously, the thickness of the dielectric layer DL can be precisely controlled using atomic layer deposition (ALD) techniques, and in that sense, according to the embodiment, the dielectric layer thickness defines the distance from the source/drain junctions to the gate electrode edges, shown as a first distance D1, or underlap distance, in FIGS. 4, 6 and 12.

Finally, in FIG. 4, the field-effect semiconductor device 1 according to one embodiment of the invention is formed by depositing a gate electrode GE in the second gate recess space RS2.

FIG. 5 is a cross-sectional view of another embodiment of the invention at an early stage of manufacture, comprising a substrate layer SL, a source region S and a drain region D, a dummy gate DG, a dummy dielectric DD, a pair of first gate insulating spacers S11 and S12 presenting two lateral side walls SW1 and SW2 and two outer surface profiles SP1 and SP2 where the lateral side walls meet the substrate layer SL, and a pair of second gate insulating spacers S21 and S22.

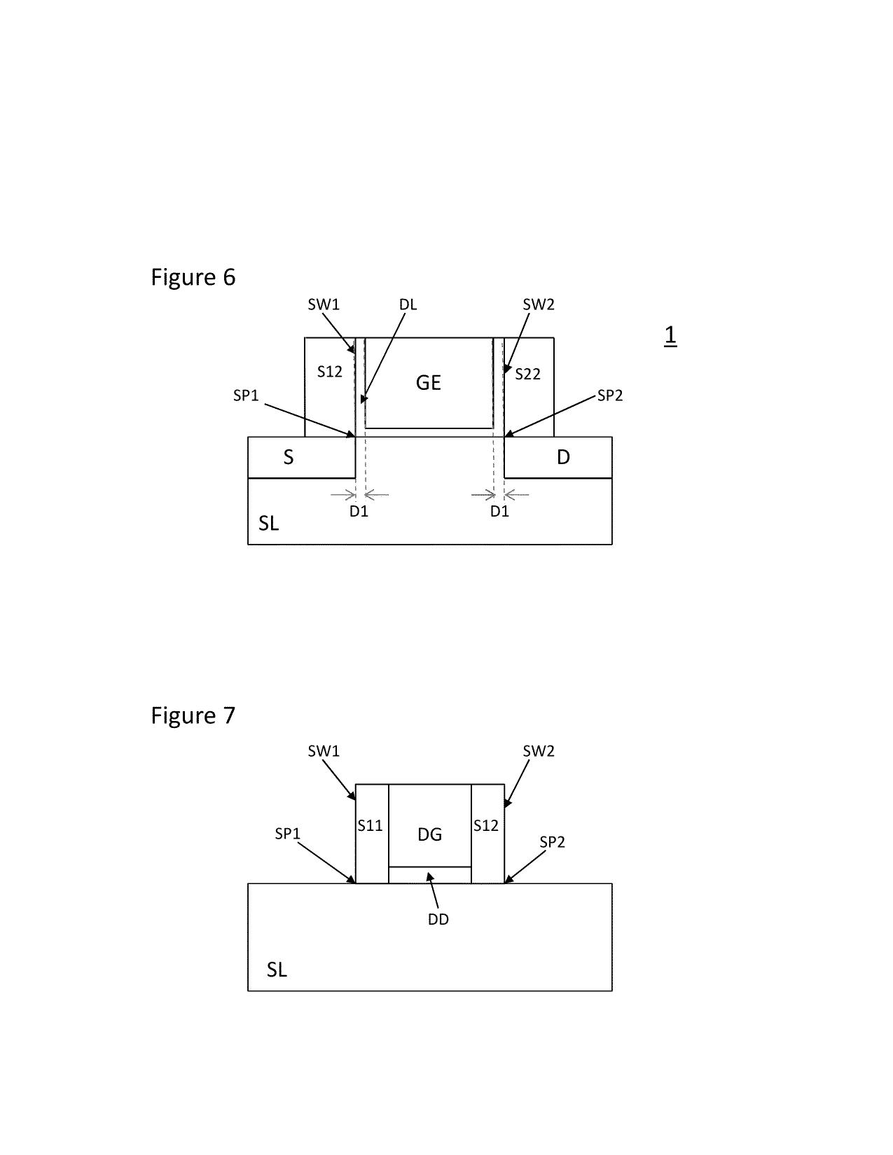

Manufacturing of the field-effect semiconductor device 1 of FIG. 6 may begin by forming the embodiment of FIG. 5 according to the following: in a first step a temporary dummy dielectric DD and a temporary dummy gate DG are formed over a substrate layer SL; in a second step, a pair of temporary first gate insulating spacers S11 and S12 are formed adjacent to the sidewalls of the dummy gate DG and over the substrate layer SL so that the temporary first gate insulating spacers present two lateral side walls SW1 and SW2 and two outer surface profiles SP1 and SP2 where the lateral side walls meet the substrate layer SL; in a third step, a source region S and a drain region D are formed in the substrate layer SL using the surface profiles of the temporary gate insulating spacers lateral side walls; in a fourth step, a pair of second gate insulating spacers S21 and S22 are formed adjacent to the sidewalls of the temporary first gate insulating spacers S11 and S12 and over the source and drain regions.

According to one embodiment of the invention, as shown in FIG. 5, the source and drain regions are formed in the substrate layer SL and extend along the temporary first gate insulating spacers lateral side walls surface profiles SP1 and SP2. In order to form the source/drain regions, for example, the surface profiles of the temporary gate insulating spacers lateral side walls is used as a mask in order to align the source/drain regions, in the substrate layer, to those surface profiles.

Similarly to the embodiment of FIG. 2, in subsequent steps of manufacture of the field-effect semiconductor device 1 of FIG. 6, the temporary dummy gate DG, the temporary dummy dielectric DD and the temporary first gate insulating spacers S11 and S12 are removed, so as to form a first gate recess space RS1.

Also similarly to the embodiment shown in FIG. 3, in a subsequent step of manufacture of the field-effect semiconductor device 1 of FIG. 6, a dielectric layer DL is deposited in the first gate recess space RS1, along the side walls of the second gate sidewall insulating spacers S21 and S22 and over the substrate layer SL, so as to form a second gate recess space RS2.

Finally, as shown in FIG. 6, the field-effect semiconductor device 1 according to one embodiment of the invention is formed by depositing a gate electrode GE in the second gate recess space RS2.

It shall be understood that the embodiment of FIG. 6 differs from the embodiment of FIG. 4 in the position of the source and drain regions, but a similar purpose is achieved, so as to align the source/drain regions to the surface profiles of the temporary first gate insulating spacers lateral side walls SW1 and SW2 in order to precisely control the underlap distance D1.

FIG. 7 shows a cross-sectional view of another embodiment of the invention at an early stage of manufacture, comprising a substrate layer SL, a dummy gate DG, a dummy dielectric DD and a pair of first gate insulating spacers S11 and S12 presenting two lateral side walls SW1 and SW2 and two outer surface profiles SP1 and SP2 where the lateral side walls meet the substrate layer SL.

Manufacturing of the field-effect semiconductor device 1 of FIG. 11 may begin by forming the embodiment of FIG. 7 according to the following: in a first step, a temporary dummy dielectric DD and a temporary dummy gate DG are formed over a substrate layer SL; in a second step, a pair of temporary first gate insulating spacers S11 and S12 are formed adjacent to the sidewalls of the dummy gate DG and over the substrate layer SL so that the temporary first gate insulating spacers present two lateral side walls SW1 and SW2 and two outer surface profiles SP1 and SP2 where the lateral side walls meet the substrate layer SL.

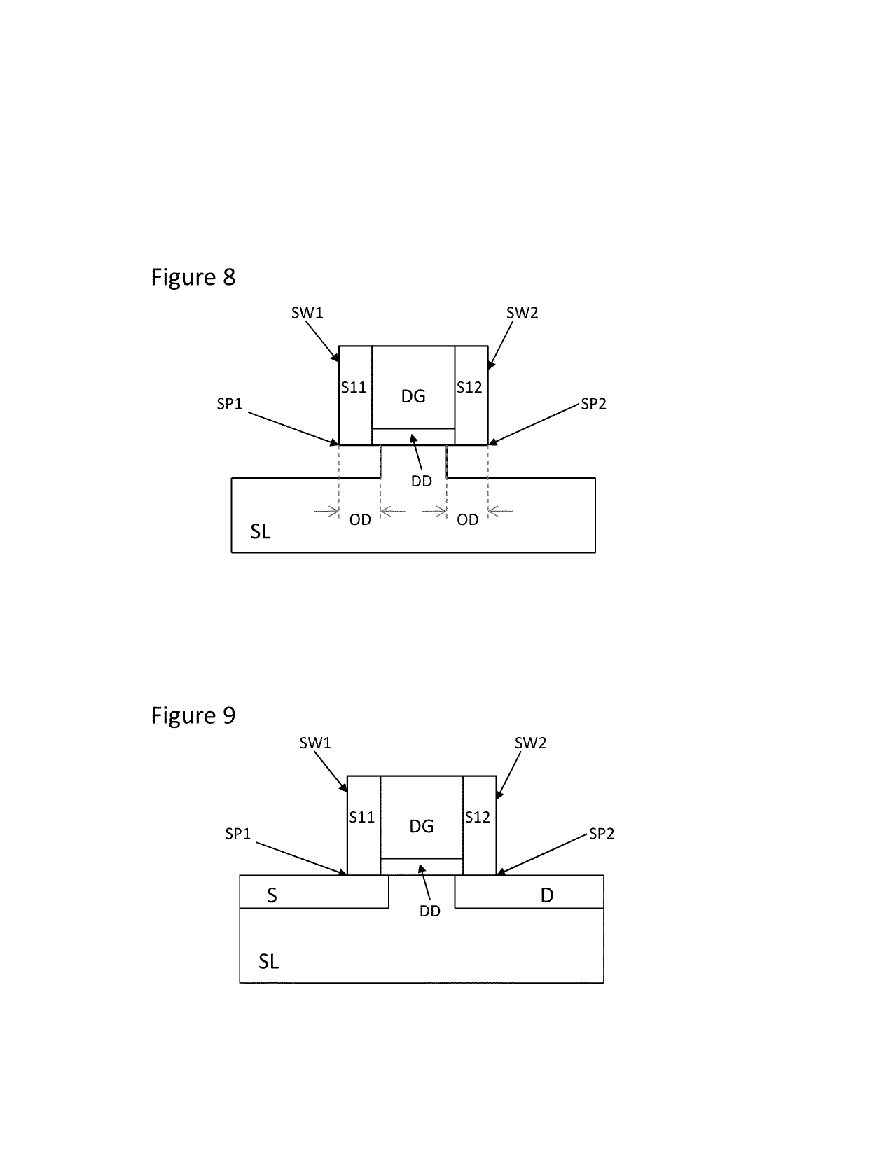

In subsequent steps of manufacture of the field-effect semiconductor device 1 of FIG. 11, an opening, extending from the surface profiles SP1 and SP2 to a predetermined distance OD in the direction of the dummy gate DG, is formed in the substrate layer SL, as shown in FIG. 8, and the opening follows or presents the same surface profile of the temporary first gate insulating spacers lateral side walls surface profile SP1 and SP2 under the dummy gate DG (when seen from a top view of the FET device).

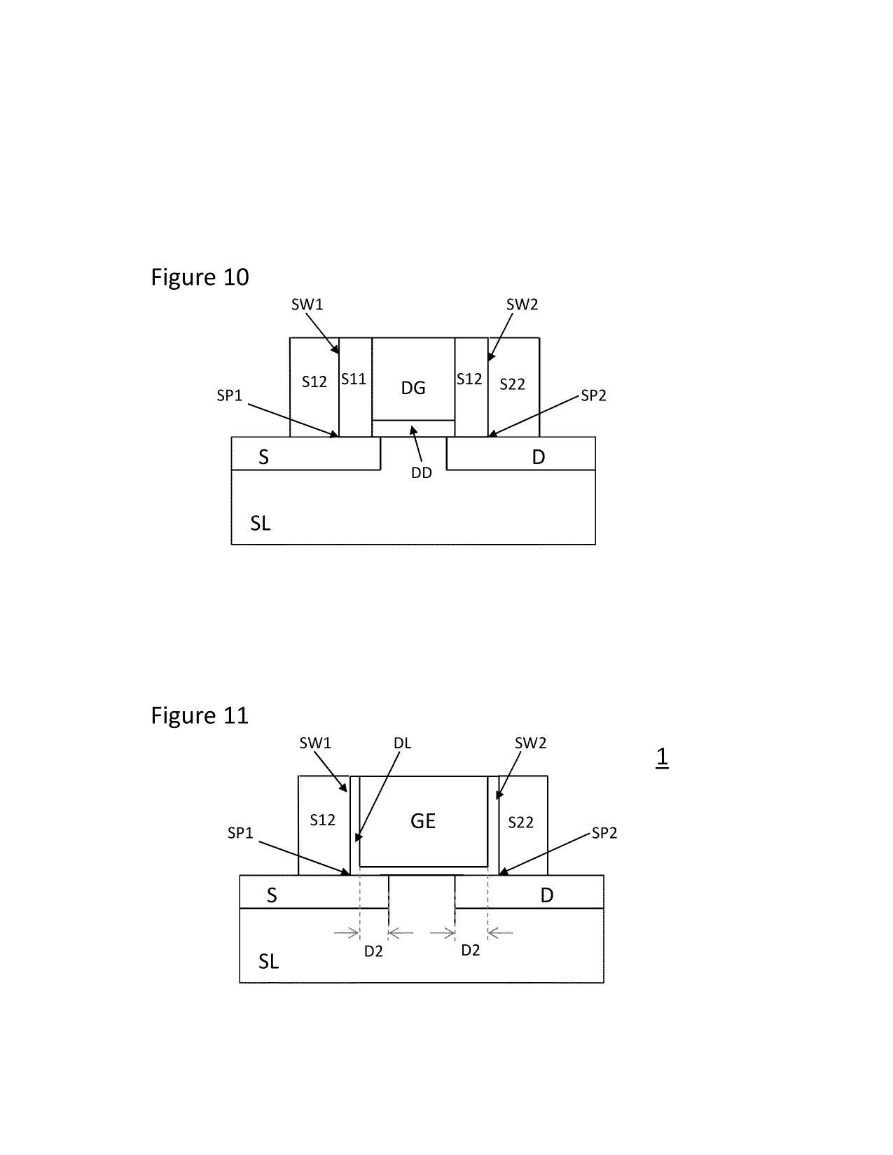

Referring next to the FIG. 9, which shows an embodiment in a subsequent step of manufacture of the field-effect semiconductor device 1 of FIG. 11, the openings are filled so as to form a source region S and a drain region D in the substrate layer SL. Then, in FIG. 10, a pair of second gate insulating spacers S21 and S22 are formed adjacent to the sidewalls of the temporary first gate insulating spacers S11 and S12 and over the source and drain regions.

Similarly to the embodiment of FIG. 2, in subsequent steps of manufacture of the field-effect semiconductor device 1 of FIG. 11, the temporary dummy gate DG, the temporary dummy dielectric DD and the temporary first gate insulating spacers S11 and S12 are removed, so as to form a first gate recess space RS1.

Also similarly to the embodiment shown in FIG. 3, in a subsequent step of manufacture of the field-effect semiconductor device 1 of FIG. 11, a dielectric layer DL is deposited in the first gate recess space RS1, along the side walls of the second gate sidewall insulating spacers S21 and S22 and over the substrate layer SL, so as to form a second gate recess space RS2. Then, in a final step, the field-effect semiconductor device 1 of FIG. 11 according to one embodiment of the invention is formed by depositing a gate electrode GE in the second gate recess space RS2.

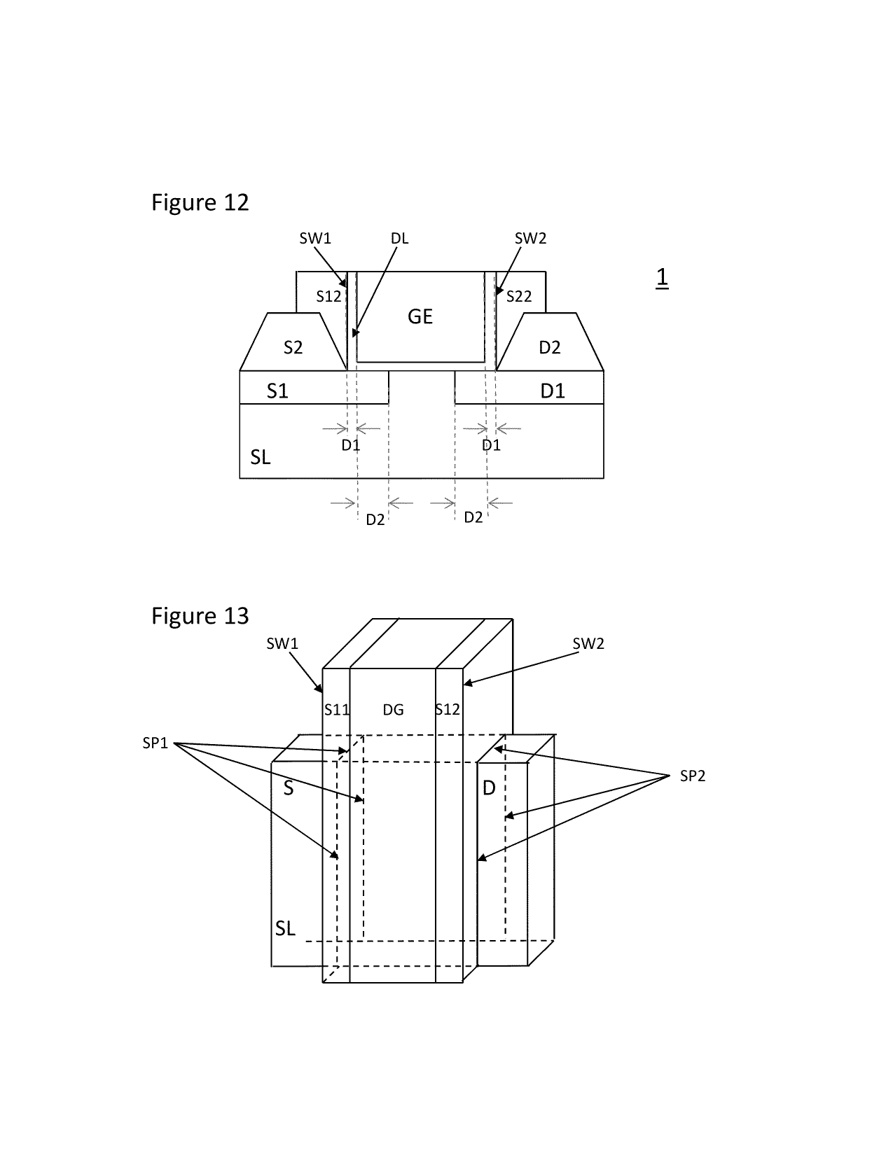

According to an embodiment of the invention, as shown in FIG. 11, the source and drain regions extend to a predetermined distance, OD in FIG. 8, from an early defined surface profile SP1 and SP2 of the temporary first gate insulating spacers lateral side walls towards the gate electrode GE, and the source and drain regions follow the surface profile of the temporary first gate insulating spacers lateral side walls SW1 and SW2 under the gate electrode. Advantageously, since both the thickness of the dielectric layer DL and the extension of the source/drain regions can be precisely controlled, both parameters can be used to precisely control a distance from the source/drain junctions under the gate electrode to the gate electrode edges, shown as a second distance D2, or overlap distance, in FIGS. 11 and 12.

FIG. 12 shows a cross-sectional view of another embodiment of a field-effect semiconductor device 1 at a final stage of manufacture, comprising a substrate layer SL, a first and a second source regions S1 and S2, a first and a second drain regions D1 and D2, a dielectric layer DL, a gate electrode GE and a pair of second gate insulating spacers S21 and S22.

It is understood by the person skilled in the art that the embodiment of FIG. 12 is manufactured similarly to the embodiment shown in FIG. 11, but further comprising second source and drain regions formed over the substrate layer which are aligned using a surface profile of the temporary gate insulating spacers lateral side walls SW1 and SW2 similarly to the embodiment shown in FIG. 4.

FIG. 13 is a simplified and schematic 3D view of a non-planar field-effect semiconductor device, such as FinFET, according to one embodiment of the invention, at an early stage of manufacture, comprising a FIN substrate layer SL, a source region S and a drain region D formed in the FIN substrate layer, a dummy gate DG, a first pair of gate insulating spacers S11 and S12 presenting two lateral side walls SW1 and SW2 in the length direction of the field-effect semiconductor device channel and two outer surface profiles SP1 and SP2 (along 3 FIN walls: front, top and back walls, as shown in the figure) where the temporary first gate insulating spacers lateral side walls SW1 and SW2 meet the FIN substrate layer SL. The embodiment shown in the figure is similar to the planar embodiment of FIG. 5 but at a stage previous to forming the second gate insulating spacers S21 and S22.

It shall be understood that the person skilled in the art will readily be able to advantageously apply the inventive aspects described hereinabove in a non-planar implementation of a FET device, in order to precisely control the source/drain-gate overlap/underlap distance along the FIN walls.

The foregoing description details certain embodiments of the invention. It will be appreciated, however, that no matter how detailed the foregoing appears in text, the invention may be practiced in many ways. It should be noted that the use of particular terminology when describing certain features or aspects of the invention should not be taken to imply that the terminology is being re-defined herein to be restricted to including any specific characteristics of the features or aspects of the invention with which that terminology is associated.

While the above detailed description has shown, described, and pointed out novel features of the invention as applied to various embodiments, it will be understood that various omissions, substitutions, and changes in the form and details of the device or process illustrated may be made by those skilled in the technology without departing from the spirit of the invention. The scope of the invention is indicated by the appended claims rather than by the foregoing description. All changes which come within the meaning and range of equivalency of the claims are to be embraced within their scope.

What is claimed is:

1. A method of manufacturing a field-effect semiconductor device comprising:
forming a temporary dummy gate over a substrate layer;
forming temporary first gate insulating spacers adjacent to the sidewalls of the dummy gate and over the substrate layer, the temporary first gate insulating spacers comprising two lateral side walls and presenting two outer surface profiles where the lateral side walls meet the substrate layer;
forming a source region and a drain region in and/or over the substrate layer using the temporary first gate insulating spacers lateral side walls surface profiles;
forming second gate insulating spacers adjacent to the sidewalls of the temporary first gate insulating spacers and over the source and drain regions;
removing the temporary dummy gate and the temporary first gate insulating spacers, thereby forming a first gate recess space;
depositing a dielectric layer in the first gate recess space along the side walls of the second gate sidewall insulating spacers and over the substrate layer, thereby forming a second gate recess space; and
depositing a gate electrode in the second gate recess space.

2. The method according to claim 1, wherein the process of forming a source region and a drain region comprises using the surface profiles of the temporary first gate insulating spacers lateral side walls to align the source/drain regions, in or over the substrate layer, to the surface profiles.

3. The method according to claim 1, wherein the process of forming a source region and a drain region comprises using the surface profiles of the temporary first gate insulating spacers lateral side walls to define the source/drain region extension, in the substrate layer, under the dummy gate.

4. The method according to claim 1, wherein the process of forming a source region and a drain region comprises using the surface profiles of the temporary first gate insulating spacers lateral side walls to align the source/drain regions, over the substrate layer, to the surface profiles and to define the source/drain region extension, in the substrate layer, under the dummy gate.

5. The method according claim 1, wherein the temporary first gate insulating spacers are removed after the temporary dummy gate removal, thereby forming a first gate recess space.

6. The method according to claim 1, the method further comprising forming a temporary dummy dielectric between the dummy gate and the substrate layer, and wherein the process of removing the temporary dummy gate and the temporary first gate insulating spacers further comprises removing the dummy dielectric, thereby forming the first gate recess space.

7. The method according to claim 1, wherein the process of removing the temporary first gate insulating spacers comprises selectively removing the material of the temporary first gate insulating spacers without substantially removing the material of the second gate insulating spacers.

8. The method according to claim 7, wherein the process of selectively removing the material of the temporary first gate insulating spaces is performed with a selectivity ration higher than about 2 to 1.

9. The method according to claim 7, wherein the temporary first gate insulating spacers are made of an oxide material and the second gate insulating spacers are made of a nitride material.

10. The method according to claim 7 wherein the temporary first gate insulating spacers are made of a nitride component deposited at temperatures lower than about 480° C. and designed to etch faster in hydrofluoric acid than the material of the second gate insulating spacers.

11. The method according to claim 1, wherein the substrate layer comprises at least one silicon wafer layer, or at least a silicon wafer layer and a quantum well layer; or at least a combination of a silicon wafer layer, a buried oxide layer and a silicon layer.

12. A field-effect semiconductor device manufactured by a method according to claim 1.

13. A method of manufacturing a semiconductor device, the method comprising:
forming first gate insulating spacers over a substrate layer and adjacent to sidewalls of a dummy gate over the substrate layer, the first gate insulating spacers comprising two lateral side walls which present two surface profiles where the lateral side walls meet the substrate layer;
forming a source region and a drain region in and/or over the substrate layer using the surface profiles as a reference point for alignment;
removing the dummy gate and the first gate insulating spacers; and
depositing a gate electrode.

14. The method according to claim 13, wherein the process of forming a source region and a drain region comprises using the surface profiles to align the source/drain regions, in or over the substrate layer, to the surface profiles.

15. The method according to claim 13, wherein the process of forming a source region and a drain region comprises using the surface profiles of the temporary first gate insulating spacers lateral side walls to define the source/drain region extension, in the substrate layer, under the dummy gate.

16. The method according to claim 13, wherein the process of forming a source region and a drain region comprises using the surface profiles of the temporary first gate insulating spacers lateral side walls to align the source/drain regions, over the substrate layer, to the surface profiles and to define the source/drain region extension, in the substrate layer, under the dummy gate.

17. The method according claim 13, wherein the first gate insulating spacers are removed after the dummy gate is removed.

18. The method according to claim 13, the method further comprising forming a dummy dielectric between the dummy gate and the substrate layer, and wherein the process of removing the dummy gate and the first gate insulating spacers further comprises removing the dummy dielectric.

19. The method according to claim 13, wherein the substrate layer comprises at least one silicon wafer layer, or at least a silicon wafer layer and a quantum well layer; or at least a combination of a silicon wafer layer, a buried oxide layer and a silicon layer.

20. A field-effect semiconductor device manufactured by a method according to claim 13.
